(19) United States
(12) Patent Application Publication
(10) Pub. No.: US 2014/0009875 A1
(43) Pub. Date: Jan. 9, 2014

(54) BASE SUBSTRATE, ELECTRONIC DEVICE, AND ELECTRONIC APPARATUS

(71) Applicant: Seiko Epson Corporation, Tokyo (JP)

(72) Inventors: Naohiro Nakagawa, Suwa (JP); Tomoyuki Kamakura, Matsumto (JP)

(21) Appl. No.: 13/924,994

(22) Filed: Jun. 24, 2013

(30) Foreign Application Priority Data
Jul. 3, 2012 (JP) 2012-149808

(51) Int. Cl. H05K 7/06

(52) U.S. Cl. CPC H05K 7/06
USPC 361/679.01; 428/448; 428/336; 428/633

(57) ABSTRACT

A base substrate includes a substrate and metal layers (a metalized layer and an electrode layer) provided on the substrate. Each metal layer includes at least a nickel-containing film which contains nickel as a material and a palladium-containing film which is located on an opposite side to the substrate with respect to the nickel-containing film and contains palladium as a material, and at least one of the nickel-containing film and the palladium-containing film contains phosphorus at a content of less than 1% by mass.

### BACKGROUND

1. Technical Field

The present invention relates to a base substrate, an electronic device, and an electronic apparatus.

2. Related Art

There has been known an electronic device having a structure in which, for example, an electronic component such as an oscillating device is housed in a package. There has also been known a package having a structure in which a plate-shaped base substrate and a cap-shaped lid are bonded to each other through a metalized layer. Further, in the base substrate, a terminal (a metal layer) for connection to the electronic component is formed. As a structure of such a terminal, for example, as disclosed in JP-A-2003-158208, there has been known a terminal including a laminate of a nickel-plated coating film having a thickness of 0.01 to 0.5 μm and a gold-plated coating film having a thickness of 0.01 to 1 μm and formed on the nickel-plated coating film. According to this structure, all of the nickel-plated coating film and the gold-plated coating film are dissolved in a solder during a solder reflow process, and therefore, an effect of achieving favorable bonding between the terminal and the solder is obtained.

However, in the metalized layer having a structure as disclosed in JP-A-2003-158208, due to a thermal load, nickel moves (diffuses) to a surface of the metalized layer, and therefore, a nickel oxide coating film may be formed on the surface of the metalized layer. Further, due to such a nickel oxide film, a problem arises that the bonding property (bonding strength) of the metalized layer to the lid is deteriorated and the airtightness when sealing is deteriorated.

### SUMMARY

An advantage of some aspects of the invention is to provide a base substrate including a metal layer having a high bonding strength, an electronic device including this base substrate and having high reliability, and an electronic apparatus including this electronic device and having high reliability.

The invention can be implemented as the following forms or application examples.

### Application Example 1

This application example of the invention is directed to a base substrate including: a substrate; and a metal layer provided on the substrate, wherein the metal layer includes at least a nickel-containing film which contains nickel as a material and a palladium-containing film which is located on an opposite side to the substrate with respect to the nickel-containing film and contains palladium as a material, and at least one of the nickel-containing film and the palladium-containing film contains phosphorus, and the content of the phosphorus is less than 1% by mass.

According to this application example, nickel can be prevented from moving (diffusing) to a surface of the metal layer, and therefore, the formation of a nickel oxide on the surface of the metal layer can be prevented. As a result, a base substrate having a high bonding strength is obtained.

### Application Example 2

In the base substrate according to the application example of the invention, it is preferred that the metal layer is a metalized layer for bonding the substrate to another member.

According to this application example, for example, the bonding between the base substrate and a lid can be more strongly and reliably achieved, and therefore, the airtightness of an internal space formed by these members can be enhanced.

### Application Example 3

In the base substrate according to the application example of the invention, it is preferred that the metal layer is an electrode layer.

According to this application example, an electrode layer having a high bonding strength is obtained.

### Application Example 4

In the base substrate according to the application example of the invention, it is preferred that the nickel-containing film and the palladium-containing film are each formed by electroless plating.

According to this application example, the nickel-containing film and the palladium-containing film can be easily formed.

### Application Example 5

In the base substrate according to the application example of the invention, it is preferred that the palladium-containing film has an average thickness of 0.15 μm or more.

According to this application example, nickel can be more effectively prevented from moving (diffusing) to a surface of the metal layer.

### Application Example 6

In the base substrate according to the application example of the invention, it is preferred that the palladium-containing film is directly superimposed on the nickel-containing film.

According to this application example, the structure of the metal layer can be further simplified.

### Application Example 7

This application example of the invention is directed to an electronic device including: a package including the base substrate according to the application example of the invention and a lid bonded to the substrate through the metal layer; and an electronic component housed in the package.

According to this application example, an electronic device having high reliability is obtained.

### Application Example 8

This application example of the invention is directed to an electronic apparatus including: the electronic device according to the application example of the invention.

According to this application example, an electronic apparatus having high reliability is obtained.

### BRIEF DESCRIPTION OF THE DRAWINGS

The invention will be described with reference to the accompanying drawings, wherein like numbers reference like elements.

FIG. 1 is a plan view of an electronic device according to a first embodiment of the invention.

FIG. 2 is a cross-sectional view of the electronic device shown in FIG. 1.

FIGS. 3A and 3B are plan views of an oscillating device of the electronic device shown in FIG. 1.

FIG. 4 is an enlarged partial cross-sectional view of a base substrate of the electronic device shown in FIG. 1.

FIGS. 5A to 5E are views for explaining a method for producing a base substrate of the electronic device shown in FIG. 1.

FIG. 6 is a cross-sectional view of a metalized layer of an electronic device according to a second embodiment of the invention.

FIG. 7 is a cross-sectional view of a metalized layer of an electronic device according to a third embodiment of the invention.

FIG. 8 is a cross-sectional view of an electronic device according to a fourth embodiment of the invention.

FIG. 9 is a perspective view showing a structure of a personal computer of a mobile type (or a notebook type), to which an electronic apparatus including the electronic device according to the embodiment of the invention is applied.

FIG. 10 is a perspective view showing a structure of a cellular phone (including also a PHS), to which an electronic apparatus including the electronic device according to the embodiment of the invention is applied.

FIG. 11 is a perspective view showing a structure of a digital still camera, to which an electronic apparatus including the electronic device according to the embodiment of the invention is applied.

FIG. 12 is a perspective view showing a structure of a mobile body (an automobile), to which an electronic apparatus including the electronic device according to the embodiment of the invention is applied.

### DESCRIPTION OF EXEMPLARY EMBODIMENTS

Hereinafter, a base substrate, an electronic device, and an electronic apparatus of the invention will be described in detail based on preferred embodiments shown in the accompanying drawings.

### First Embodiment

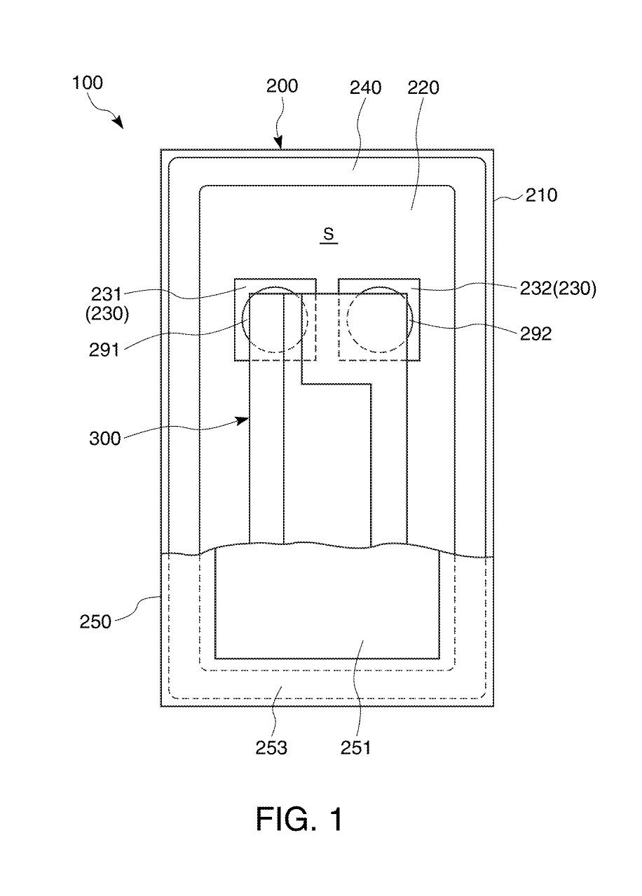

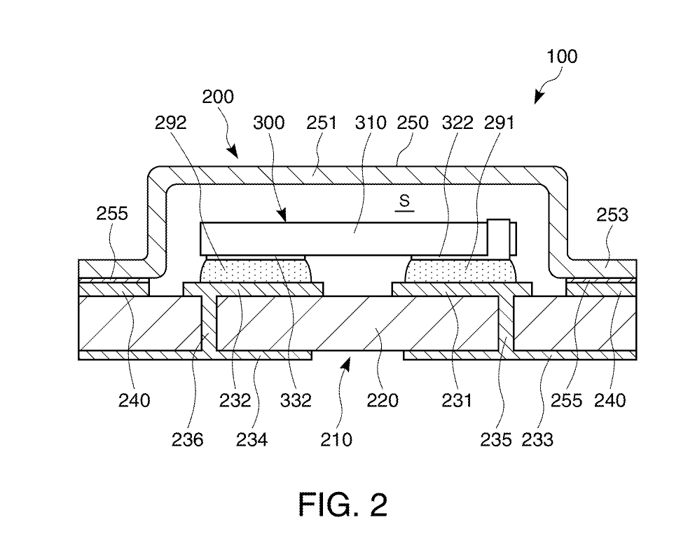

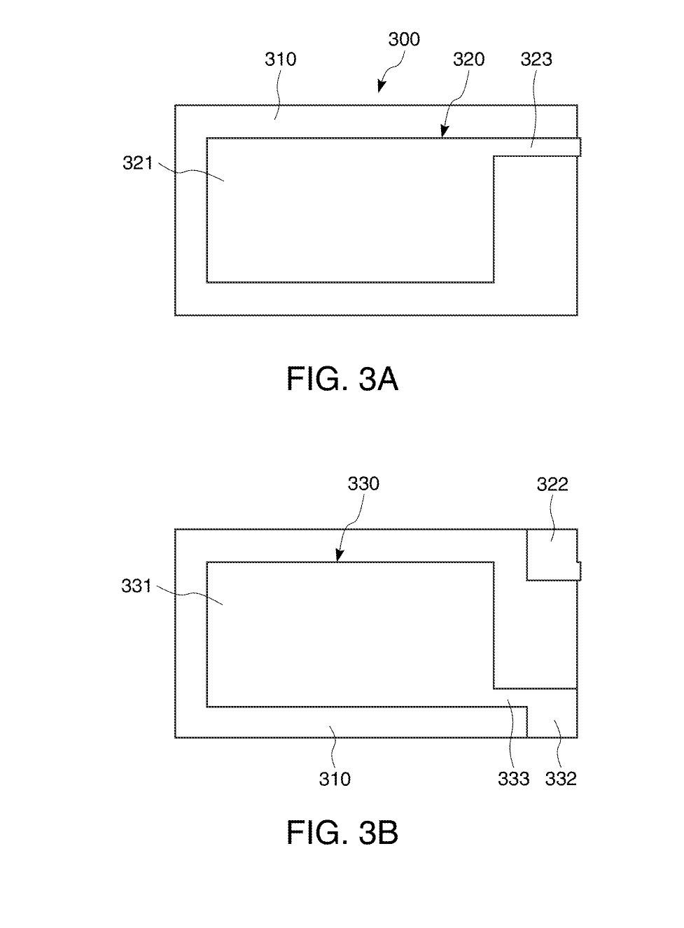

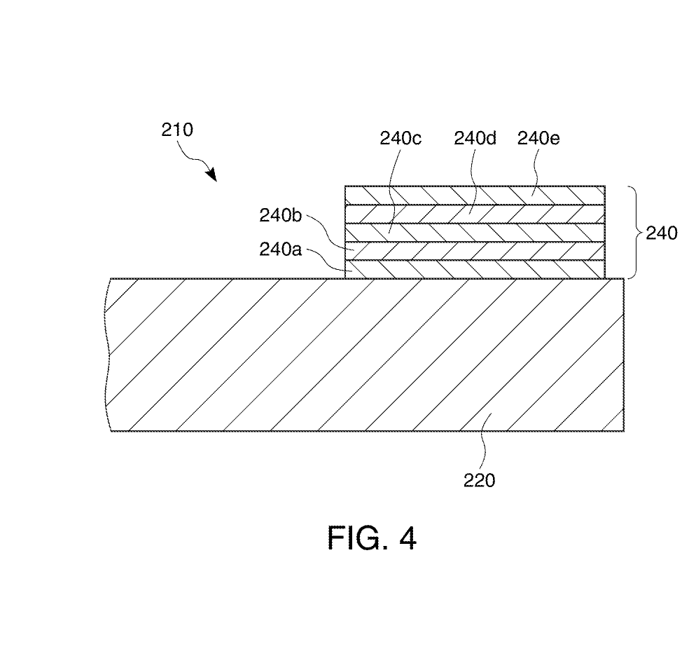

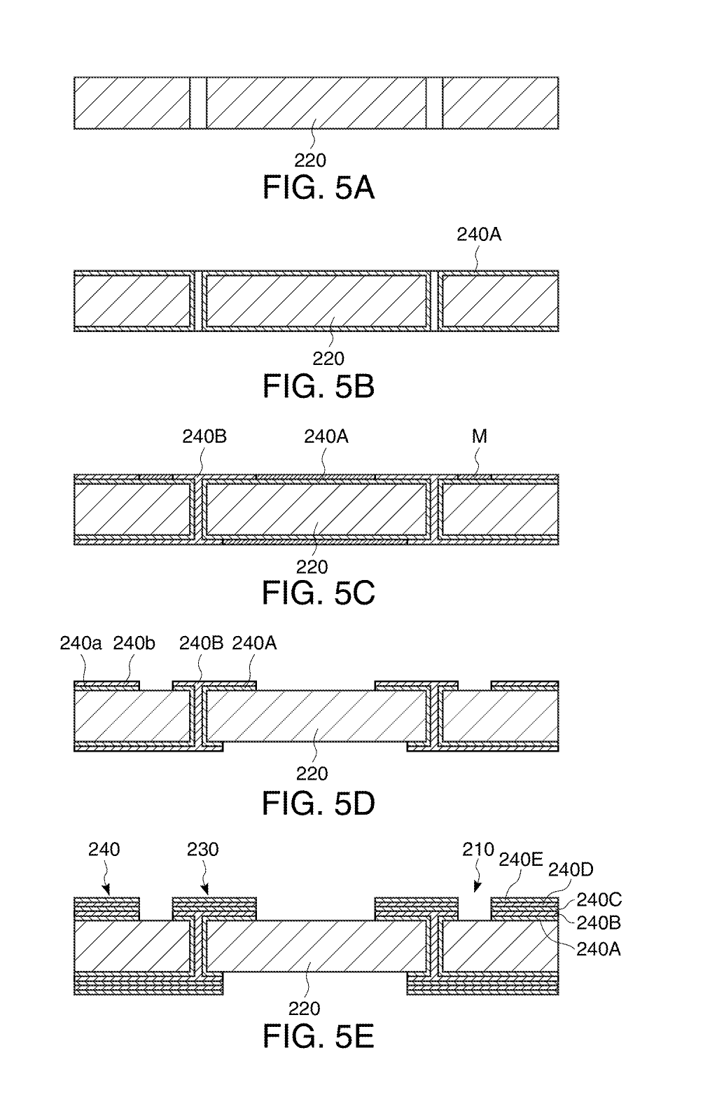

FIG. 1 is a plan view of an electronic device according to a first embodiment of the invention. FIG. 2 is a cross-sectional view of the electronic device shown in FIG. 1. FIGS. 3A and 3B are plan views of an oscillating device of the electronic device shown in FIG. 1. FIG. 4 is an enlarged partial cross-sectional view of a base substrate of the electronic device shown in FIG. 1. FIGS. 5A to 5E are views for explaining a method for producing a base substrate of the electronic device shown in FIG. 1. It is noted that, hereinafter, a description will be made with the upper side and the lower side in FIG. 2 being referred to as “upper” and “lower”, respectively, for convenience of description.

### 1. Electronic Device

First, an electronic device according to the invention will be described.

As shown in FIGS. 1 and 2, an electronic device 100 includes a package 200 and an oscillating device 300 as a functional device housed in the package 200.

### Oscillating Device

FIG. 3A is a plan view from above of the oscillating device 300, and FIG. 3B is a perspective view (a plan view) from above of the oscillating device 300.

As shown in FIGS. 3A and 3B, the oscillating device 300 includes a piezoelectric substrate 310 whose plan view shape is a rectangular (oblong) plate, and a pair of excitation electrodes 320 and 330 formed on a surface of the piezoelectric substrate 310.

The piezoelectric substrate 310 is a quartz crystal plate which mainly vibrates in a thickness shear vibration mode. In this embodiment, as the piezoelectric substrate 310, a quartz crystal plate which is cut out at a cut angle called AT cut is used. The “AT cut” refers to cutting out of a quartz crystal in such a manner that the quartz crystal has a principal plane (a principal plane including an X axis and a Z′ axis) obtained by rotating a plane (a Y plane) including the X axis and a Z axis as crystal axes of quartz crystal about the X axis at an angle of approximately 35° 15′ from the Z axis in a counterclockwise direction. In the piezoelectric substrate 310 having such a structure, its longitudinal direction coincides with the X axis which is a crystal axis of quartz crystal.

The excitation electrode 320 includes an electrode section 321 formed on an upper surface of the piezoelectric substrate 310, a bonding pad 322 formed on a lower surface of the piezoelectric substrate 310, and a wiring 323 electrically connecting the electrode section 321 to the bonding pad 322. On the other hand, the excitation electrode 330 includes an electrode section 331 formed on a lower surface of the piezoelectric substrate 310, a bonding pad 332 formed on a lower surface of the piezoelectric substrate 310, and a wiring 333 electrically connecting the electrode section 331 to the bonding pad 332. The electrode sections 321 and 331 are provided facing each other through the piezoelectric substrate 310, and the bonding pads 322 and 332 are formed spaced apart from each other at an end portion on a right side of FIG. 3B of a lower surface of the piezoelectric substrate 310.

Such excitation electrodes 320 and 330 can be formed, for example, as follows. After an underlayer of nickel (Ni) or chromium (Cr) is formed on the piezoelectric substrate 310 by vapor deposition or sputtering, an electrode layer of gold (Au) is formed on the underlayer by vapor deposition or sputtering, followed by patterning into a desired shape using photolithography or any of a variety of etching techniques. By forming the underlayer, the adhesiveness between the piezoelectric substrate 310 and the electrode layer is improved, and therefore, an oscillating device 300 having high reliability can be obtained.

Such an oscillating device 300 is fixed to the package 200 through a pair of conductive adhesives 291 and 292.

### Package

As shown in FIGS. 1 and 2, the package 200 includes a plate-shaped base substrate 210, and a cap-shaped lid 250 having a recess which is open toward a lower side. In such a package 200, the opening of the lid 250 is closed with the base substrate 210, whereby a storage space S in which the oscillating device 300 described above is stored is formed.

The lid 250 includes a main body 251 having a bottomed cylindrical shape and a flange 253 formed on a lower edge of the main body 251 (i.e., a circumference of an opening of the main body 251). A constituent material of such a lid 250 is not particularly limited, but is preferably a material having a linear expansion coefficient approximate to that of the constituent material of the base substrate 210. For example, when a ceramic as described below is used as the constituent material of the base substrate 210, an alloy such as kovar is preferably used as the constituent material of the lid 250.

Further, on a lower surface of the flange 253, a solder material 255 is provided in the form of a film so as to cover the circumference of the opening. The solder material 255 can be formed by, for example, a screen printing method. The solder material 255 is not particularly limited, and a gold solder, a silver solder, etc. can be used, however, it is preferred to use a silver solder. Further, the melting point of the solder material 255 is not particularly limited, but is preferably about 800° C. or higher and 1000° C. or lower. If the solder material has such a melting point, a package 200 which is suitable for laser sealing is formed.

On the other hand, the base substrate 210 includes a plate-shaped substrate 220, and an electrode layer (a metal layer) 230 and a metalized layer (a metal layer) 240, both of which are formed on the substrate 220.

A constituent material of the substrate 220 is not particularly limited as long as it has an insulating property, and for example, any of a variety of ceramics such as oxide-based ceramics, nitride-based ceramics, and carbide-based ceramics, or the like can be used.

The electrode layer 230 includes a pair of connection electrodes 231 and 232 provided on an upper surface (a plane facing the storage space S) of the substrate 220, a pair of externally mounted electrodes 233 and 234 provided on a lower surface of the substrate 220, and a pair of through electrodes 235 and 236 which are provided penetrating the substrate 220 and connect the connection electrodes 231 and 232 to the externally mounted electrodes 233 and 234, respectively.

The metalized layer 240 is provided in the form of a frame along a peripheral portion of an upper surface of the substrate 220. Further, the metalized layer 240 is provided in non-contact with the electrode layer 230. Such a metalized layer 240 is provided between the substrate 220 and the flange 253 of the lid 250, and the substrate 220 and the lid 250 are bonded to each other at the region where the metalized layer 240 is provided. According to this, the inner portion (the storage space S) of the package 200 is hermetically sealed.

In the storage space S, the oscillating device 300 is stored. The oscillating device 300 stored in the storage space S is cantilevered by the base substrate 210 through a pair of conductive adhesives 291 and 292. The conductive adhesive 291 is provided in contact with the connection electrode 231 and the bonding pad 322. According to this, the connection electrode 231 and the bonding pad 322 are electrically connected to each other through the conductive adhesive 291. Meanwhile, the other conductive adhesive 292 is provided in contact with the connection electrode 232 and the bonding pad 332. According to this, the connection electrode 232 and the bonding pad 332 are electrically connected to each other through the conductive adhesive 292.

Hereinabove, the structure of the electronic device 100 has been briefly described.

Next, the structures of the electrode layer 230 and the metalized layer 240 will be described. The structures of the electrode layer 230 and the metalized layer 240 are the same as each other, and therefore, in the following description, for convenience of description, the metalized layer 240 will be described as a representative, and a description of the electrode layer 230 will be omitted. Further, the structure of the metalized layer 240 described below is a structure before the metalized layer 240 and the lid 250 are subjected to laser sealing.

As shown in FIG. 4, the metalized layer 240 is composed of a laminate in which a plurality of metal films are laminated, and in the plurality of metal films, at least a Ni-containing film which contains Ni (nickel) as a material and a Pd-containing film which is located on an opposite side to the substrate 220 with respect to the Ni-containing film and contains Pd (palladium) as a material are included. Further, at least one of the Ni-containing film and the Pd-containing film contains phosphorus at a content of less than 1% by mass. According to the configuration of the metalized layer 240, nickel is prevented from moving to a surface (an outermost layer) of the metalized layer 240, whereby the metalized layer 240 has an excellent bonding property.

Here, it is preferred that the Ni-containing film and the Pd-containing film are each formed by electroless plating. By using this process, these films can be formed easily. The method for forming the Ni-containing film and the Pd-containing film is not limited to electroless plating, and the films may be formed by, for example, electrolytic plating.

The number of metal films constituting the metalized layer 240 is not particularly limited, but is preferably about 5. According to this, the number of metal films is not too large, and therefore, the metalized layer 240 is easily formed. Further, the metalized layer 240 can be prevented from being too thick, and for example, stress remaining in the metalized layer 240 can be made further smaller. As a result, a package 200 having a small residual stress as a whole can be obtained.

The average thickness of the metalized layer 240 is not particularly limited, but is preferably about 10 μm or more and 20 μm or less. According to this, the base substrate 210 and the lid 250 can be strongly bonded to each other while suppressing a residual stress in the metalized layer 240. In addition, the package 200 can be prevented from being too thick.

Specifically, the metalized layer 240 of this embodiment is composed of a laminate in which a first metal film 240a, a second metal film 240b, a third metal film 240c, a fourth metal film 240d, and a fifth metal film 240e are laminated in this order from the side of the substrate 220.

As the first metal film 240a, for example, a metal film composed of a metal material such as Cr (chromium), Mo (molybdenum), or W (tungsten), an alloy containing any of these metal materials, or the like can be preferably used. Such a first metal film 240a can be formed by, for example, vapor deposition or sputtering. Further, the first metal film 240a is used as, for example, a seed layer in the case where the second metal film. 240b is formed by electrolytic plating. The average thickness of the first metal film 240a is not particularly limited, but is preferably about 0.2 μm or more and 0.5 μm or less.

As the second metal film 240b, for example, a metal film composed of Au (gold), Ag (silver), Cu (copper), or an alloy containing at least one of these metals (as a main component) can be preferably used. The average thickness of the second metal film 240b is not particularly limited, but is preferably about 5 μm or more and 15 μm or less. Such a second metal film 240b can be formed by, for example, electrolytic plating using the first metal film 240a as a seed layer. However, the method for forming the second metal film 240a is not particularly limited, and the film can also be formed by, for example, sputtering or any of various gas phase deposition methods such as vapor deposition.

The third metal film 240c functions as a barrier layer that protects the second metal film 240b. Such a third metal film 240c is composed of a Ni—P coating film (a Ni-containing film). It is preferred that the content of Ni in the third metal film 240c is about 88 to 96% by mass, and the content of P therein is about 4 to 12% by mass. Further, in the third metal film 240c, other than Ni and P, another metal material such as Co (cobalt), W (tungsten), or Mo (molybdenum) may be contained.

The average thickness of the third metal film 240c is not particularly limited, but is preferably about 1 μm or more and 3 μm or less. By setting the thickness in such a range, a sufficient thickness for exhibiting the above-described function can be ensured and also the third metal film 240c can be prevented from being too thick.

Further, as described above, the third metal film 240c is preferably formed by electroless plating. By using the electroless plating process, the third metal film 240c can be easily formed.

The fourth metal film 240d functions as a barrier layer that prevents Ni contained in the third metal film 240c from moving to the fifth metal film 240e. Such a fourth metal film 240d is composed of a pure Pd coating film (a Pd-containing film). The fourth metal film 240d substantially does not contain metal materials other than Pd. That is, in the fourth metal film 240d, P is not contained (the concentration of P in the fourth metal film 240d is 0% by mass). Accordingly, by the fourth metal film 240d, Ni contained in the third metal film 240c can be prevented from moving to an outermost surface of the metalized layer 240.

To be more specific, for example, when a thermal load is applied to the metalized layer 240 by laser sealing or the like, P (phosphorus) in the third metal film 240c moves to a surface side of the metalized layer 240, and also Ni (nickel) in the third metal film 240c moves to a surface side of the metalized layer 240 along with the movement of P (phosphorus). However, in this embodiment, the movement of P (phosphorus) can be prevented by the fourth metal film 240d, and due to this, the movement of Ni (nickel) to an outermost surface of the metalized layer 240 can be prevented. If Ni moves to an outermost surface (an outermost layer: the fifth metal film 240e) of the metalized layer 240, a Ni oxide film is formed on the outermost surface of the metalized layer 240, and due to a harmful effect of this Ni oxide film, a problem arises that the welding property (bonding property) of the metalized layer 240 is deteriorated. On the other hand, according to this embodiment, the formation of a Ni oxide film on an outermost surface can be prevented, and therefore, deterioration of the welding property can be prevented, and an excellent welding property can be exhibited. Accordingly, the airtightness of the storage space S can be enhanced.

Further, by forming the fourth metal film. 240d which is a Pd-containing film on the third metal film 240c which is a Ni-containing film, in other words, by directly overlapping the fourth metal film 240d and the third metal film 240c with each other, the effect described above can be more effectively exhibited, and for example, the number of metal films constituting the metalized layer 240 can be suppressed, and therefore, the structure of the metalized layer 240 can be further simplified.

The average thickness of the fourth metal film 240d is not particularly limited, but is preferably about 0.15 μm or more and 1 μm or less. By setting the thickness in such a range, a sufficient thickness for exhibiting the above-described function can be ensured and also the fourth metal film 240d can be prevented from being too thick.

Further, as described above, the fourth metal film 240d is preferably formed by electroless plating. By using the electroless plating process, the fourth metal film 240d can be easily formed.

Incidentally, in the fourth metal film 240d, P (phosphorus) may be contained as long as the content of P is less than 1% by mass, and even in this case, the same effect as described above can be exhibited.

The fifth metal film 240e is a film for preventing the oxidation of the metalized layer 240, that is, an antioxidant film. Such a fifth metal film 240e can be constituted by, for example, a gold (Au) coating film. The average thickness of the fifth metal film 240e is not particularly limited, but is preferably about 0.05 μm or more and 0.3 μm or less. By setting the thickness in such a range, a sufficient thickness for exhibiting the above-described function can be ensured and also the fifth metal film 240e can be prevented from being too thick.

Such a fifth metal film 240e diffuses in the fourth metal film 240d and the like and may substantially disappear when the metalized layer 240 and the lid 250 are subjected to laser sealing.

Hereinabove, the structure of the metalized layer 240 has been described in detail. As described above, the electrode layer 230 has the same structure as the metalized layer 240, and therefore, the electrode layer 230 can exhibit an effect as follows. That is, in the same manner as the metalized layer 240, the formation of a Ni oxide film on an outermost surface of the electrode layer 230 can be prevented, and therefore, the adhesiveness of the conductive adhesives 291 and 292 to the connection electrodes 231 and 232 is improved. As a result, the oscillating device 300 can be more strongly fixed to the package 200. In addition, if the above-described Ni oxide film is formed, there is a possibility that a part of the Ni oxide film is detached (peeled) from the electrode layer 230, and the detached oxide film piece is attached to the oscillating device 300 to deteriorate the performance of the oscillating device 300. However, according to this embodiment, such a problem is not caused, and accordingly, an electronic device 100 which exhibits excellent reliability can be provided.

### 2. Method for Producing Base Substrate

Next, a method for producing the base substrate 210 will be described. It is noted that the method for producing the base substrate 210 is not limited to the method described below.

First, as shown in FIG. 5A, a plate-shaped substrate 220 is prepared. The substrate 220 is obtained by shaping a mixture including a starting material powder containing a ceramic or a glass, an organic solvent, and a binder into a sheet by a doctor blade method, etc., thereby obtaining a ceramic green sheet, firing the obtained ceramic green sheet, and then, forming through-holes at desired positions (where via holes are formed). At this time, it is also possible to fire a laminate in which a plurality of ceramic green sheets are laminated.

Subsequently, as shown in FIG. 5B, a Cr coating film 240A composed of chromium (Cr) is formed on a surface of the substrate 220 by, for example, sputtering. In the case where, for example, the aspect ratio of the through-hole is large (the through-hole is oblong), or the like, before forming the Cr coating film 240A, a metal material may be buried in the through-hole in advance.

Subsequently, as shown in FIG. 5C, a mask M is formed in shapes corresponding to the shapes of the metalized layer 240 and the electrode layer 230 on the Cr coating film 240A by photolithography. Subsequently, plating is performed by electrolytic copper plating, whereby a Cu coating film 240B (a second metal film 240b) is formed in regions (i.e., regions corresponding to the metalized layer 240 and the electrode layer 230) exposed from the mask M on the Cr coating film. 240A. At this time, the plating is filled in the through-holes, whereby through-hole electrodes 235 and 236 are formed.

Subsequently, as shown in FIG. 5D, after the mask M is removed, by using the second metal film 240b as a mask, the Cr coating film 240A is patterned by wet etching. By doing this, a first metal film 240a is formed.

Subsequently, as shown in FIG. 5E, electroless Ni—P plating, electroless pure Pd plating, and electroless gold plating are sequentially performed, whereby a Ni—P coating film 240C (a third metal film 240c), a pure Pd coating film 240D (a fourth metal film 240d), and an Au coating film 240E (a fifth metal film 240e) are sequentially formed on the second metal film 240b.

As described above, the base substrate 210 is produced.

### Second Embodiment

Next, a second embodiment of the electronic device according to the invention will be described.

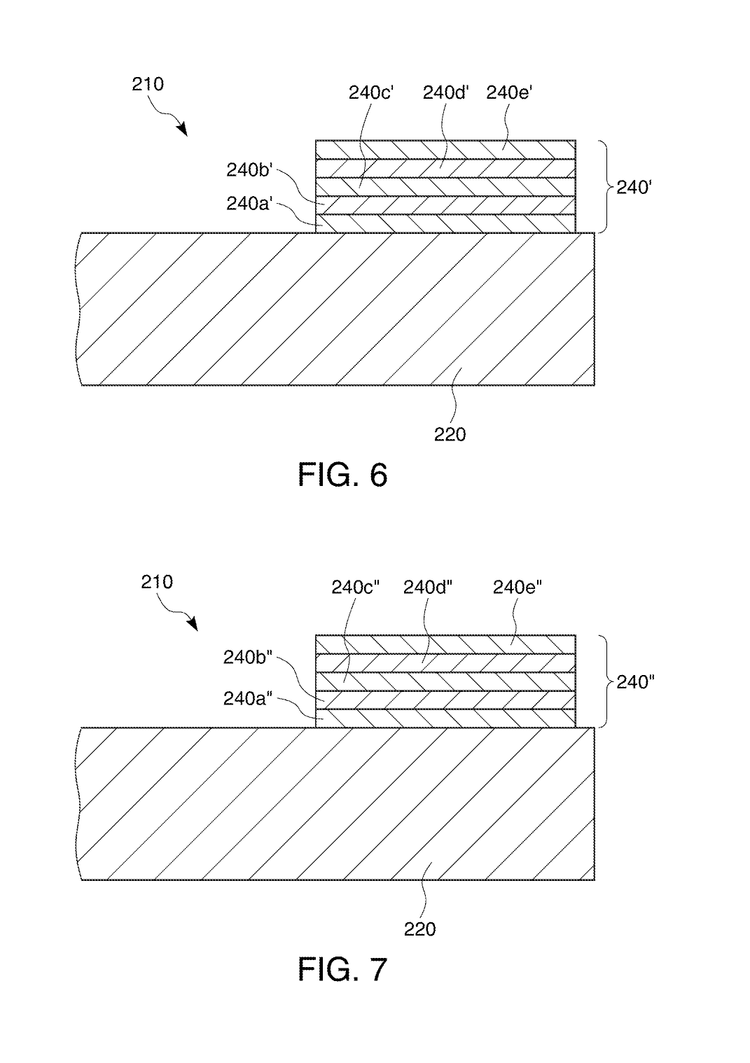

FIG. 6 is a cross-sectional view of a metalized layer of an electronic device according to the second embodiment of the invention.

Hereinafter, with respect to the electronic device according to the second embodiment, different points from those of the embodiment described above will be mainly described and a description of the same matters will be omitted.

The electronic device of the second embodiment of the invention is the same as that of the first embodiment described above except that the structures of the metalized layer and the electrode layer are different. Incidentally, the same components as those of the first embodiment described above are denoted by the same reference signs. In this embodiment, the structures of the metalized layer and the electrode layer are the same as each other, and therefore, in the following description, the metalized layer will be described as a representative, and a description of the electrode layer will be omitted.

A metalized layer 240′ shown in FIG. 6 is composed of a laminate in which a first metal film. 240a′, a second metal film 240b′, a third metal film 240c‘, a fourth metal film 240d’, and a fifth metal film 240e′ are laminated in this order from the side of the substrate 220. Among these films, the first, second, and fifth metal films 240a′, 240b′, and 240e′ have the same structures as the first, second, and fifth metal films 240a, 240b, and 240e in the first embodiment described above.

The third metal film 240c′ functions as a barrier layer that protects the second metal film 240b′ in the same manner as in the first embodiment described above. Such a third metal film 240c′ is composed of a Ni—B coating film (a Ni-containing film). It is preferred that the content of B (boron) in the third metal film 240c′ is about less than 3.0% by mass. Further, in the third metal film 240c′, other than Ni and B, another metal material such as Co (cobalt), W (tungsten), or Mo (molybdenum) may be contained. In addition, in the third metal film 240c′, P (phosphorus) may be contained as long as the content of P is less than 1.0% by mass.

The average thickness of the third metal film 240c′ is not particularly limited, but is preferably about 1 μm or more and 3 μm or less. By setting the thickness in such a range, a sufficient thickness for exhibiting the above-described function can be ensured and also the third metal film 240c′ can be prevented from being too thick.

Further, the third metal film 240c′ is preferably formed by electroless plating. By using the electroless plating process, the third metal film 240c′ can be easily formed.

The fourth metal film 240d′ is composed of a Pd—P coating film (a Pd-containing film). It is preferred that the content of Pd in the fourth metal film 240d′ is about 88 to 96% by mass, and the content of P therein is about 4 to 12% by mass. Further, in the fourth metal film 240d′, other than Pd and P, another metal material such as Co (cobalt), W (tungsten), or Mo (molybdenum) may be contained.

The average thickness of the fourth metal film. 240d′ is not particularly limited, but is preferably about 0.15 μm or more and 1 μm or less. By setting the thickness in such a range, a sufficient thickness for exhibiting the above-described function can be ensured and also the fourth metal film 240d′ can be prevented from being too thick.

Further, the fourth metal film 240d′ is preferably formed by electroless plating. By using the electroless plating process, the fourth metal film 240d′ can be easily formed.

Hereinabove, the metalized layer 240′ of this embodiment has been described. Also by the metalized layer 240′, the formation of a Ni oxide film is prevented and the metalized layer 240′ has an excellent welding property in the same manner as in the first embodiment described above. To be more specific, in the third metal film 240c′ which is a Ni-containing film, P (phosphorus) is not contained (or even if P is contained, the content of P is very small), and therefore, the movement of P (phosphorus) due to a thermal load as described above in the first embodiment is not caused, and the movement of Ni along with the movement of P is not caused either. On the other hand, P (phosphorus) in the fourth metal film 240d′ moves to an outermost surface of the metalized layer 240′, however, in the fourth metal film 240d′, Ni (nickel) is not contained, and therefore, the movement of Ni is not caused. Accordingly, the formation of a Ni oxide film on the outermost surface of the metalized layer 240′ is prevented, and the effect described above can be reliably exhibited.

According also to the second embodiment, the same effect as the first embodiment described above can be exhibited.

### Third Embodiment

Next, a third embodiment of the electronic device according to the invention will be described.

FIG. 7 is a cross-sectional view of a metalized layer of an electronic device according to the third embodiment of the invention.

Hereinafter, with respect to the electronic device according to the third embodiment, different points from those of the embodiments described above will be mainly described and a description of the same matters will be omitted.

The electronic device of the third embodiment of the invention is the same as that of the first embodiment described above except that the structures of the metalized layer and the electrode layer are different. Incidentally, the same components as those of the first embodiment described above are denoted by the same reference signs. In this embodiment, the structures of the metalized layer and the electrode layer are the same as each other, and therefore, in the following description, the metalized layer will be described as a representative, and a description of the electrode layer will be omitted.

A metalized layer 240″ shown in FIG. 7 is composed of a laminate in which a first metal film. 240a″, a second metal film 240b″, a third metal film 240c″, a fourth metal film 240d″, and a fifth metal film 240e″ are laminated in this order from the side of the substrate 220. Among these films, the first, second, and fifth metal films 240a″, 240b″, and 240e″ have the same structures as the first, second, and fifth metal films 240a, 240b, and 240e in the first embodiment.

The third metal film 240c″ functions as a barrier layer that protects the second metal film 240b″ in the same manner as in the first embodiment described above. Such a third metal film 240c″ is composed of a Ni—B coating film (a Ni-containing film). It is preferred that the content of B (boron) in the third metal film 240c″ is about less than 3.0% by mass. Further, in the third metal film 240c″, other than Ni and B, another metal material such as Co (cobalt), W (tungsten), or Mo (molybdenum) may be contained. In addition, in the third metal film 240c″, P (phosphorus) may be contained as long as the content of P is less than 1.0% by mass.

The average thickness of the third metal film 240c″ is not particularly limited, but is preferably about 1 μm or more and 3 μm or less. By setting the thickness in such a range, a sufficient thickness for exhibiting the above-described function can be ensured and also the third metal film 240c″ can be prevented from being too thick.

Further, the third metal film 240c″ is preferably formed by electroless plating. By using the electroless plating process, the third metal film 240c″ can be easily formed.

The fourth metal film 240d″ is composed of a pure Pd coating film (a Pd-containing film). Such a fourth metal film 240d″ substantially does not contain metal materials other than Pd. That is, in the fourth metal film 240d″, P is not contained (the concentration of P in the fourth metal film 240d″ is 0% by mass). Incidentally, in the fourth metal film 240d″, P (phosphorus) may be contained as long as the content of P is less than 1.0% by mass.

The average thickness of the fourth metal film 240d″ is not particularly limited, but is preferably about 0.15 μm or more and 1 μm or less. By setting the thickness in such a range, a sufficient thickness for exhibiting the above-described function can be ensured and also the fourth metal film 240d″ can be prevented from being too thick.

Further, the fourth metal film 240d″ is preferably formed by electroless plating. By using the electroless plating process, the fourth metal film 240d″ can be easily formed.

Hereinabove, the metalized layer 240″ of this embodiment has been described. Also by the metalized layer 240″, the formation of a Ni oxide film is prevented and the metalized layer 240″ has an excellent welding property in the same manner as in the first embodiment described above. To be more specific, in either of the third metal film. 240c″ which is a Ni-containing film and the fourth metal film 240d″ which is a Pd-containing film, P (phosphorus) is not contained (or even if P is contained, the content of P is very small), and therefore, the movement of P (phosphorus) due to a thermal load as described above in the first embodiment is not caused, and the movement of Ni along with the movement of P is not caused either. Accordingly, the formation of a Ni oxide film on an outermost surface of the metalized layer 240″ is prevented, and the effect described above can be reliably exhibited.

According also to the third embodiment, the same effect as the first embodiment described above can be exhibited.

### Fourth Embodiment

Next, a fourth embodiment of the electronic device according to the invention will be described.

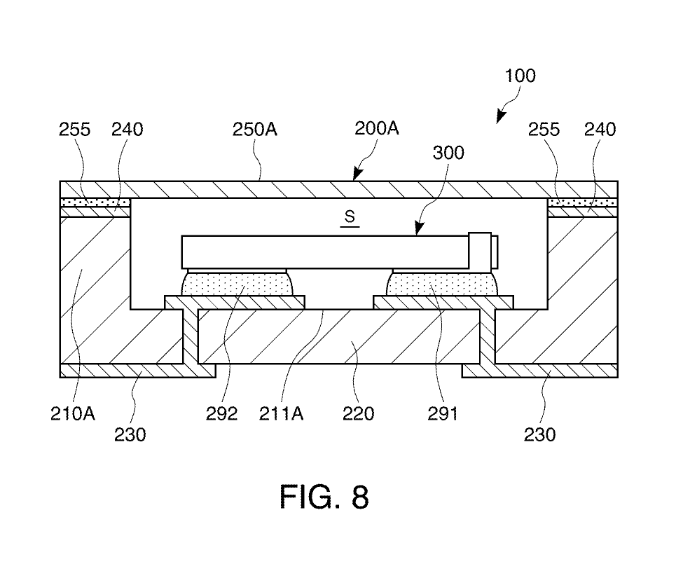

FIG. 8 is a cross-sectional view of an electronic device according to the fourth embodiment of the invention.

Hereinafter, with respect to the electronic device according to the fourth embodiment, different points from those of the embodiments described above will be mainly described and a description of the same matters will be omitted.

The electronic device of the fourth embodiment of the invention is the same as that of the first embodiment described above except that the structure of the package is different. Incidentally, the same components as those of the first embodiment described above are denoted by the same reference signs.

In an electronic device 100 shown in FIG. 8, a package 200A includes a base substrate 210A having a recess 211A which is open toward an upper surface, and a plate-shaped lid 250A provided so as to cover the opening of the recess 211A. In such a package 200A, an oscillating device 300 is stored in the recess 211A.

According also to the fourth embodiment, the same effect as that of the first embodiment described above can be exhibited.

### Electronic Apparatus

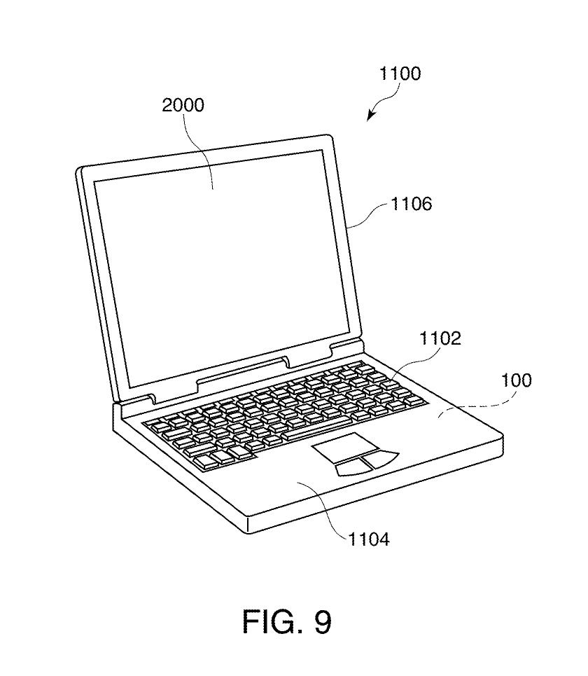

Next, an electronic apparatus (an electronic apparatus according to the invention) to which the electronic device of the embodiment of the invention is applied will be described in detail with reference to FIGS. 9 to 12.

FIG. 9 is a perspective view showing a structure of a personal computer of a mobile type (or a notebook type), to which an electronic apparatus including the electronic device of the embodiment of the invention is applied. In this drawing, a personal computer 1100 includes a main body 1104 provided with a key board 1102, and a display unit 1106 provided with a display section 2000. The display unit 1106 is supported rotatably with respect to the main body 1104 via a hinge structure section. In such a personal computer 1100, an electronic device 100 which functions as a filter, an oscillator, a reference clock, or the like is incorporated.

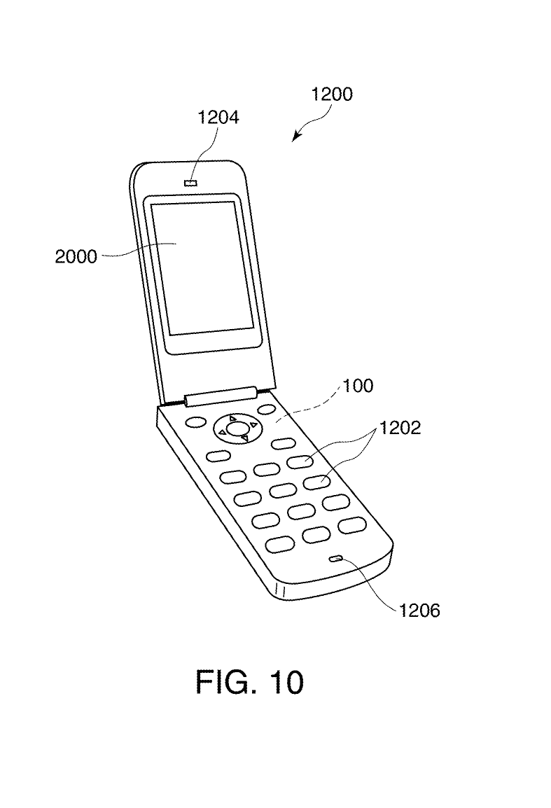

FIG. 10 is a perspective view showing a structure of a cellular phone (including also a PHS), to which an electronic apparatus including the electronic device of the embodiment of the invention is applied. In this drawing, a cellular phone 1200 includes a plurality of operation buttons 1202, an earpiece 1204, and a mouthpiece 1206, and between the operation buttons 1202 and the earpiece 1204, a display section 2000 is placed. In such a cellular phone 1200, an electronic device 100 which functions as a filter, an oscillator, or the like is incorporated.

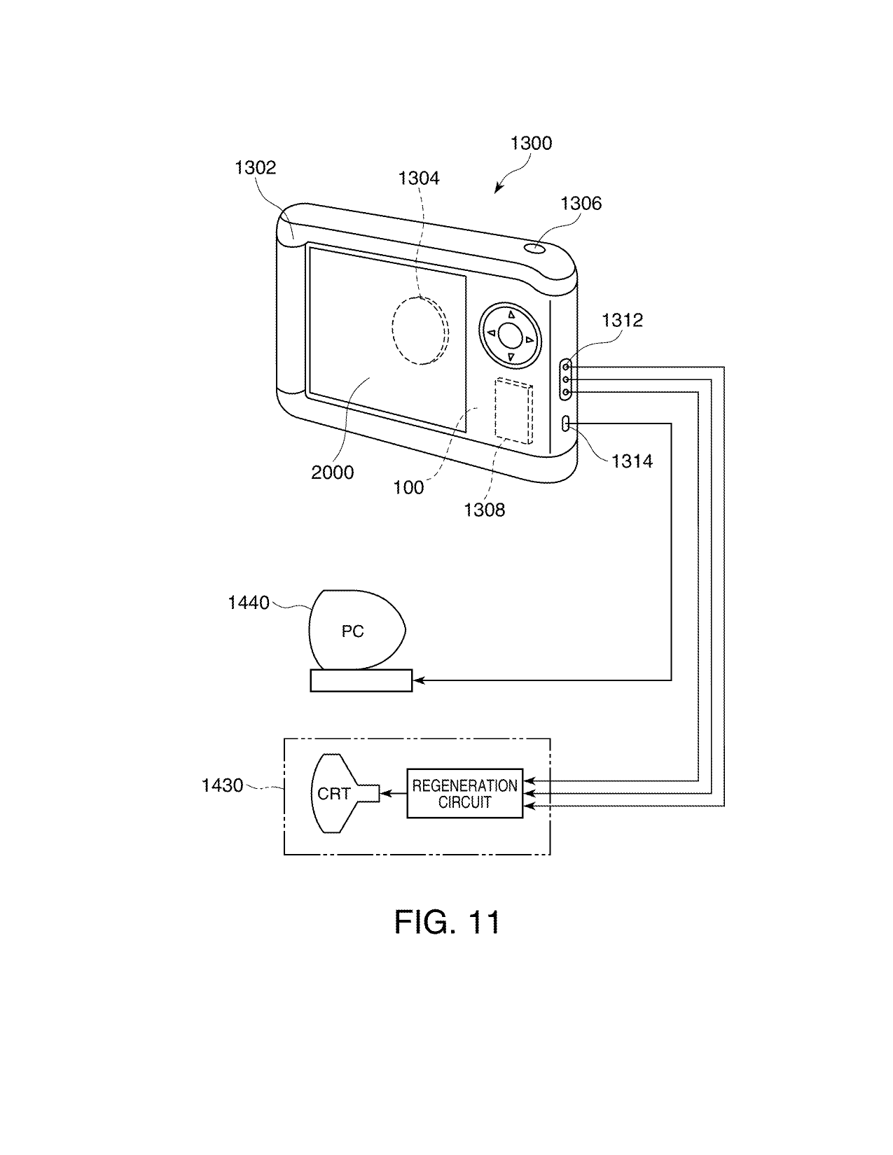

FIG. 11 is a perspective view showing a structure of a digital still camera, to which an electronic apparatus including the electronic device of the embodiment of the invention is applied. In this drawing, connection to external apparatuses is also briefly shown. A usual camera exposes a silver salt photographic film to light on the basis of an optical image of a subject. On the other hand, a digital still camera 1300 generates an imaging signal (an image signal) by photoelectrically converting an optical image of a subject into the imaging signal with an imaging device such as a CCD (Charge Coupled Device).

On a back surface of a case (body) 1302 in the digital still camera 1300, a display section is provided, and the display section is configured to perform display on the basis of the imaging signal of the CCD. The display section functions as a finder which displays a subject as an electronic image. Further, on a front surface side (on a back surface side in the drawing) of the case 1302, a light receiving unit 1304 including an optical lens (an imaging optical system), a CCD, etc. is provided.

When a person who takes a picture confirms an image of a subject displayed on the display section and pushes a shutter button 1306, an imaging signal of the CCD at that time is transferred to a memory 1308 and stored there. Further, a video signal output terminal 1312 and an input/output terminal 1314 for data communication are provided on a side surface of the case 1302 in the digital still camera 1300. As shown in the drawing, a television monitor 1430 and a personal computer 1440 are connected to the video signal output terminal 1312 and the input/output terminal 1314 for data communication, respectively, as needed. Moreover, the digital still camera 1300 is configured such that the imaging signal stored in the memory 1308 is output to the television monitor 1430 or the personal computer 1440 by means of a predetermined operation. In such a digital still camera 1300, an electronic device 100 which functions as a filter, an oscillator, or the like is incorporated.

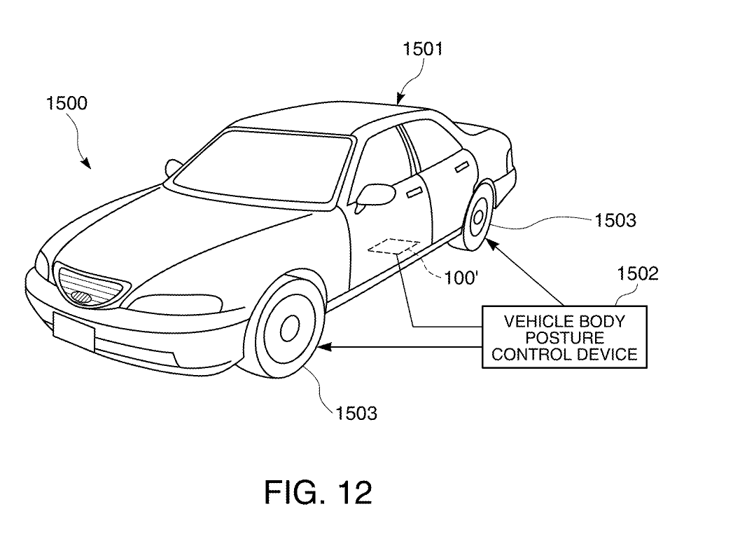

FIG. 12 is a perspective view showing a structure of a mobile body (an automobile), to which an electronic apparatus including the electronic device of the embodiment of the invention is applied. In an automobile 1500, for example, the electronic device of the embodiment of the invention is incorporated as a gyro sensor. In this case, an electronic device 100′ in which as the functional device, an angular velocity detecting device is used in place of the oscillating device 300 can be used. According to this electronic device 100′, a posture of a vehicle body 1501 can be detected. A detection signal from the electronic device 100′ is supplied to a vehicle body posture control device 1502. The vehicle body posture control device 1502 detects a posture of the vehicle body 1501 on the basis of the signal and can control a stiffness of a suspension or a brake for an individual wheel 1503 according to the detection result. Such posture control can be utilized in a robot walking with two legs or a radio control helicopter other than the automobile. As described above, in order to realize posture control of a variety of mobile bodies, the electronic device 100′ is incorporated.

Incidentally, the electronic apparatus including the electronic device of the embodiment of the invention can be applied to, other than the personal computer (mobile personal computer) shown in FIG. 9, the cellular phone shown in FIG. 10, the digital still camera shown in FIG. 11, and the mobile body shown in FIG. 12, for example, inkjet type ejection apparatuses (e.g., inkjet printers), laptop personal computers, televisions, video cameras, videotape recorders, car navigation devices, pagers, electronic notebooks (including those having a communication function), electronic dictionaries, pocket calculators, electronic game devices, word processors, work stations, television telephones, television monitors for crime prevention, electronic binoculars, POS terminals, medical devices (e.g., electronic thermometers, blood pressure meters, blood sugar meters, electrocardiogram measuring devices, ultrasound diagnostic devices, and electronic endoscopes), fish finders, various measurement devices, gauges (e.g., gauges for vehicles, airplanes, and ships), flight simulators, etc.

Hereinabove, the base substrate, the electronic device, and the electronic apparatus of the invention have been described based on the embodiments shown in the drawings, but the invention is not limited to the embodiments. The respective components can be replaced with components having an arbitrary structure capable of functioning in the same manner. Further, any other arbitrary structure may be added to the invention. In addition, the respective embodiments may be appropriately combined.

### EXAMPLES

### 1. Production of Substrate

### Example 1

First, a ceramic substrate obtained by using alumina as a starting material and having a thickness of 300 μm was prepared. Subsequently, a Cr film having an average thickness of 0.2 μm was formed on the ceramic substrate by vapor deposition. Subsequently, a Cu film having an average thickness of 10 μm was formed on the Cr film by electrolytic plating. Subsequently, a Ni—P film having an average thickness of 2 μm was formed on the Cu film by electroless plating. Subsequently, a pure Pd film having an average thickness of 0.3 μm was formed on the Ni—P film by electroless plating. Subsequently, an Au film having an average thickness of 0.05 μm was formed on the pure Pd film by electroless plating. In this manner, a base substrate of Example 1 in which metal layers (a metalized layer and a layer corresponding to an electrode layer) were formed on a substrate was obtained. The concentration of P in the Ni—P film was 0.8%.

### Example 2

A base substrate of Example 2 was obtained in the same manner as in the above-described Example 1 except that the average thickness of the pure Pd film was changed to 0.15 μm.

### Example 3

A base substrate of Example 3 was obtained in the same manner as in the above-described Example 1 except that the average thickness of the pure Pd film was changed to 0.10 μm.

### Example 4

First, a ceramic substrate obtained by using alumina as a starting material and having a thickness of 300 μm was prepared. Subsequently, a Cr film having an average thickness of 0.2 μm was formed on the ceramic substrate by vapor deposition. Subsequently, a Cu film having an average thickness of 10 μm was formed on the Cr film by electrolytic plating. Subsequently, a Ni—B film having an average thickness of 2 μm was formed on the Cu film by electroless plating. Subsequently, a Pd—P film having an average thickness of 0.45 μm was formed on the Ni—B film by electroless plating. Subsequently, an Au film having an average thickness of 0.05 μm was formed on the Pd—P film by electroless plating. In this manner, a base substrate of Example 4 in which metal layers (a metalized layer and a layer corresponding to an electrode layer) were formed on a substrate was obtained. The concentration of P in the Pd—P film was 0.7%.

### Example 5

First, a ceramic substrate obtained by using alumina as a starting material and having a thickness of 300 μm was prepared. Subsequently, a Cr film having an average thickness of 0.2 μm was formed on the ceramic substrate by vapor deposition. Subsequently, a Cu film having an average thickness of 10 μm was formed on the Cr film by electrolytic plating. Subsequently, a Ni—B film having an average thickness of 2 μm was formed on the Cu film by electroless plating. Subsequently, a pure Pd film having an average thickness of 0.3 μm was formed on the Ni—B film by electroless plating. Subsequently, an Au film having an average thickness of 0.05 μm was formed on the pure Pd film by electroless plating. In this manner, a base substrate of Example 5 in which metal layers (a metalized layer and a layer corresponding to an electrode layer) were formed on a substrate was obtained.

### Comparative Example 1

First, a ceramic substrate obtained by using alumina as a starting material and having a thickness of 300 μm was prepared. Subsequently, a Cr film having an average thickness of 0.2 μm was formed on the ceramic substrate by vapor deposition. Subsequently, a Cu film having an average thickness of 10 μm was formed on the Cr film by electrolytic plating. Subsequently, a Ni—P film having an average thickness of 2 μm was formed on the Cu film by electroless plating. Subsequently, a Pd—P film having an average thickness of 0.3 μm was formed on the Ni—P film by electroless plating. Subsequently, an Au film having an average thickness of 0.05 μm was formed on the Pd—P film by electroless plating. In this manner, a base substrate of Comparative Example 1 in which metal layers (a metalized layer and a layer corresponding to an electrode layer) were formed on a substrate was obtained.

### 2. Evaluation

For the respective Examples 1 to 5 and Comparative Example 1, the amount of Ni on a surface of the metal layer before and after a heat treatment was quantitatively analyzed, and whether or not Ni moved to the surface and the amount of Ni that moved to the surface were determined. As the heat treatment, heating was performed in a vacuum atmosphere at 275° C. for 12 hours, and thereafter, heating was further performed in a N₂ atmosphere at 300° C. for 2 hours. Further, the quantitative analysis of the amount of Ni was performed by X-ray photoelectron spectroscopy (XPS analysis). The results are shown in the following Table 1.

TABLE 1

Amount of Ni (%)

| | Before heat | After heat |
|---|---|---|
| | treatment | treatment |
| Example 1 | 0 | 0.1 |
| Example 2 | 0 | 0 |
| Example 3 | 0 | 0.2 |
| Example 4 | 0 | 0 |
| Example 5 | 0 | 0 |
| Comparative Example 1 | 0.1 | 13.6 |

From Table 1, it is found that in each of the cases of Examples 1 to 5, almost no Ni moved (diffused) to the surface of the metal layer. On the other hand, it is found that in the case of Comparative Example 1, a large amount of Ni moved to the surface of the metal layer.

The entire disclosure of Japanese Patent Application No. 2012-149808, filed Jul. 3, 2012 is expressly incorporated by reference herein.

What is claimed is:

1. A base substrate, comprising:
a substrate; and
a metal layer provided above the substrate, wherein
the metal layer includes at least a nickel-containing film which contains nickel as a material and a palladium-containing film which is located on an opposite side to the substrate with respect to the nickel-containing film and contains palladium as a material, and
at least one of the nickel-containing film and the palladium-containing film contains phosphorus, and the content of the phosphorus is less than 1% by mass.

2. The base substrate according to claim 1, wherein the metal layer is an electrode layer.

3. The base substrate according to claim 1, wherein the nickel-containing film and the palladium-containing film are each formed by electroless plating.

4. The base substrate according to claim 1, wherein the palladium-containing film has an average thickness of 0.15 μm or more.

5. The base substrate according to claim 1, wherein the palladium-containing film is directly superimposed above the nickel-containing film.

6. An electronic device, comprising:
a package including the base substrate according to claim 1 and a lid bonded to the substrate through the metal layer; and
an electronic component housed in the package.

7. An electronic apparatus, comprising the electronic device according to claim 6.
